(19) United States
(12) Patent Application Publication
(10) Pub. No.: US 2025/0372525 A1
(43) Pub. Date: Dec. 4, 2025

(54) PACKAGE DEVICE AND MANUFACTURING METHOD THEREOF

(71) Applicant: InnoLux Corporation, Miao-Li County (TW)

(72) Inventors: Ker-Yih KAO, Miao-Li County (TW); Po-Yun HSU, Miao-Li County (TW); Ju-Li WANG, Miao-Li County (TW)

(73) Assignee: InnoLux Corporation, Miao-Li County (TW)

(21) Appl. No.: 19/192,366

(22) Filed: Apr. 29, 2025

Related U.S. Application Data
(60) Provisional application No. 63/652,186, filed on May 28, 2024.

(30) Foreign Application Priority Data
Dec. 31, 2024 (CN) 202411976291.8

(51) Int. Cl. H01L 23/538; H01L 21/48; H01L 21/66; H01L 23/15; H01L 23/498

(52) U.S. Cl. CPC H01L 23/5384; H01L 21/486; H01L 22/12; H01L 23/5386; H01L 23/15; H01L 23/49894

(57) ABSTRACT

A package device is provided and includes a substrate and a conductive element. The substrate includes a through hole, a first portion, and a second portion, wherein the through hole penetrates the first portion and the second portion, and a first thickness of the first portion is less than a second thickness of the second portion. The conductive element is disposed in the through hole, wherein the first portion of the substrate includes compressive stress, and the second portion of the substrate includes tensile stress.

### CROSS REFERENCE TO RELATED APPLICATION

This application claims the benefit of U.S. Provisional Application No. 63/652,186, filed on May 28, 2024. The content of the application is incorporated herein by reference.

### BACKGROUND OF THE DISCLOSURE

### 1. Field of the Disclosure

The present disclosure relates to a semiconductor package technology, and particularly to a package device with a strengthened substrate and manufacturing method thereof.

### 2. Description of the Prior Art

With the development of the technology, since the number of chips adopting semiconductor package in the electronic device increases, and the performance of the chips has to be enhanced, the package technology of using a substrate as support has been developed. However, micro cracks are easily produced in the process of forming a through hole in the substrate. Also, the process of forming circuits or other elements on the substrate includes multiple thermal processes, such that the problem of micro cracks is aggravated, even causing the substrate to breakage or resulting in a poor yield or reliability of the product.

### SUMMARY OF THE DISCLOSURE

It is an objective of the present disclosure to provide a package device and manufacturing method thereof to solve the aforementioned problems.

According to an embodiment of the present disclosure, a package device is provided and includes a substrate and a conductive element. The substrate includes a through hole, a first portion, and a second portion, wherein the through hole penetrates the first portion and the second portion, and a first thickness of the first portion is less than a second thickness of the second portion. The conductive element is disposed in the through hole, wherein the first portion of the substrate includes compressive stress, and the second portion of the substrate includes tensile stress.

According to another embodiment of the present disclosure, a manufacturing method of a package device is provided and includes the following steps. Firstly, a substrate is provided, and a first modification process is performed on the substrate. Afterwards, an etching process is performed to form a patterned substrate, wherein the patterned substrate includes a through hole. Then, a first inspection process is performed on the patterned substrate to determine if the patterned substrate is a qualified product after the etching process. When the patterned substrate is determined to be the qualified product, a second modification process is performed to form a first portion and a second portion in the patterned substrate, wherein the patterned substrate includes a surface, the first portion is closer to the surface than the second portion, and a first thickness of the first portion is less than a second thickness of the second portion. The first portion includes compressive stress, and the second portion includes tensile stress. Afterwards, a metallization process is performed to form a conductive element in the through hole.

In the package device and manufacturing method thereof of the present disclosure, since the second modification process may form the first portion including compressive stress and the second portion including tensile stress in the substrate, and since the first portion is closer to the surface than the second portion, under the condition that there are cracks in the substrate, the probability of the cracks deteriorating or expanding may be reduced in the following thermal processes, and the reliability and/or yield of the product is enhanced.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 schematically illustrates a flow chart of a manufacturing method of a package device according to a first embodiment of the present disclosure.

FIG. 2 to FIG. 7 schematically illustrate structures in different steps of the manufacturing method of the package device according to the first embodiment of the present disclosure.

FIG. 8 to FIG. 9 schematically illustrate structures in different steps of a manufacturing method of a package device according to a second embodiment of the present disclosure.

FIG. 10 to FIG. 13 schematically illustrate structures in different steps of a manufacturing method of a package device according to a third embodiment of the present disclosure.

FIG. 14 to FIG. 16 schematically illustrate structures in different steps of a manufacturing method of a package device according to a fourth embodiment of the present disclosure.

FIG. 17 schematically illustrates a cross-sectional view of a package device according to a modified embodiment of the fourth embodiment of the present disclosure.

FIG. 18 schematically illustrates a cross-sectional view of a package device according to a fifth embodiment of the present disclosure.

FIG. 19 schematically illustrates a cross-sectional view of a package device according to a sixth embodiment of the present disclosure.

FIG. 20 schematically illustrates a cross-sectional view of a package device according to a seventh embodiment of the present disclosure.

### DETAILED DESCRIPTION

The contents of the present disclosure will be described in detail with reference to specific embodiments and drawings. It is noted that, for purposes of illustrative clarity and ease of understanding by the readers, the following drawings in the present disclosure may be a simplified illustrations, and elements therein may not be drawn to scale. The numbers and sizes of the elements in the drawings are merely illustrative and are not intended to limit the scope of the present disclosure.

Certain terms are used throughout the specification and the appended claims of the present disclosure to refer to specific elements. Those skilled in the art should understand that electronic equipment manufacturers may refer to an element by different names, and this document does not intend to distinguish between elements that differ in name but not in function. In the following specification and claims, the terms “comprise”, “include” and “have” are open-ended fashion, so they should be interpreted as “including but not limited to . . . ”.

The ordinal numbers used in the specification and the appended claims, such as “first”, “second”, etc., are used to describe the elements of the claims. This does not mean that the element has any previous ordinal numbers, nor does this represent the order of a certain element and another element, or the sequence in a manufacturing method. These ordinal numbers are merely used to make a claimed element with a certain name be clearly distinguishable from another claimed element with the same name.

In addition, when one element or layer is “connected to” another element or layer, it may be understood that the element or layer is directly connected to the another element or layer physically or electrically, and alternatively, the two may be physically or electrically connected through other element or layer (indirectly). On the contrary, when the element or layer is “directly connected to” another element or layer, it may be understood that there is no other element or layer between the two for physical or electrical connection. The term “connect” may include means of “directly connect” or “indirectly connect”. Besides, the term “electrically connect” or “couple” includes any direct or indirect means of electrical connection.

In the present disclosure, when one element is “disposed on” another element, the manufacturing procedure or sequence of forming the element and the another element is not limited thereto. In the present disclosure, when one element is “disposed on” another element, it may include one element is disposed on a side wall of another element.

As disclosed herein, the terms “approximately”, “essentially”, “about”, or “substantially” generally mean within 108, 58, 3%, 2%, 1%, or 0.5% of the reported numerical value or range. The numbers given herein are approximated numbers, and that is, without specifically describing with the terms “approximately”, “essentially”, “about”, or “substantially”, it may still imply the meaning of the terms “approximately”, “essentially”, “about”, or “substantially”.

The term “between a number A and a number B” is interpreted as including the number A and the number B or as including at least one of the number A and the number B, and as including other numbers between the number A and the number B.

In the present disclosure, the depth, length, thickness, width, height, distance, and aperture may be measured by using an optical microscope (OM), a scanning electron microscope (SEM) or other approaches, but not limited thereto.

In the present disclosure, the definition of roughness may be a distance of 0.15 μm to 1 μm between peaks and valleys of surface undulations observed by a SEM. The measurement of determining the roughness may include using a SEM or a transmission electron microscope (TEM), etc. to observe peaks and valleys of surface undulations in a proper magnified ratio, and comparing the surface undulations by taking a unit length (e.g., 10 μm) to obtain its roughness range. Here, the term “proper magnified ratio” means at least one surface may be observed a roughness (Rz) or an averaged roughness (Ra) with at least 10 peaks in the visual field in this magnified ratio.

It should be understood that, according to the following embodiments, features of different embodiments may be replaced, recombined or mixed to constitute other embodiments without departing from the spirit of the present disclosure. The features of various embodiments may be mixed arbitrarily and used in different embodiments without departing from or conflicting with the spirit of the present disclosure.

Unless otherwise defined, all terms (including technical and scientific terms) used herein have the same meaning as commonly understood by those skilled in the art. It should be understood that these terms, such as those defined in commonly used dictionaries, should be interpreted as having meaning consistent with the relevant technology and the background or context of the present disclosure, and should not be interpreted in an idealized or excessively formal way, unless there is a specific definition in the embodiments of the present disclosure.

A package device of the present disclosure may, for example, be applied to any kinds of electronic devices. The electronic device may, for example, include a display device, a light emitting device, a sensing device, an antenna device, a touch device, a tiled device, a package device, or other suitable electronic devices, but not limited thereto. The electronic device may, for example, be a bendable, stretchable, foldable, rollable, and/or flexible electronic device, but not limited thereto. The display device may, for example, be applied to a laptop, a public display, a tiled display, a car display, a touch display, a TV, a monitor, a smartphone, a tablet, a light source module, a lighting equipment, a military equipment, or an electronic device applied to the aforementioned products, but not limited thereto. The sensing device may, for example, be a sensing device used for detecting variation in capacitances, light, heat, or ultrasound, but not limited thereto. The sensing device may, for example, include a bio-sensor, a touch sensor, a fingerprint sensor, other suitable sensors, or any combination of the aforementioned sensors. The display device may, for example, include liquid crystal molecules, a light emitting diode, a fluorescent material, a phosphor material, other suitable display media, or a combination of the aforementioned display media, but not limited thereto. The light emitting diode may, for example, include an organic light emitting diode (OLED), a mini light emitting diode (mini LED), a micro light emitting diode (micro LED), or a quantum dot light emitting diode (e.g., QLED or QDLED), but not limited thereto. The antenna device may include liquid crystal antenna, varactor diode antenna, or antennas of other types, but not limited thereto. The tiled device may, for example, include a tiled display device or a tiled antenna device, but not limited thereto. Furthermore, the appearance of the electronic device may be, for example, rectangular, circular, polygonal, a shape with curved edges, curved or other suitable shapes. The electronic device may have peripheral systems, such as a driving system, a control system, a light source system, a shelf system, etc. The electronic device may include electronic units, in which the electronic units may include a passive element and an active element, and for example, include a capacitor, a resistor, an inductor, a diode, a transistor, a sensor, etc. It is noted that the electronic device of the present disclosure may be any combination of the above-mentioned devices, but not limited thereto. The manufacturing method of the package device of the present disclosure may, for example, be applied to a wafer-level package (WLP) process or a panel-level package (PLP) process, wherein the WLP or the PLP may include a chip-first process or a chip-last process, but not limited thereto. The package device of the present disclosure may, for example, be applied to a power module, a display device, a light emitting device, a backlight device, an antenna device, a sensing device, or a tiled device, but not limited thereto. The package device may include system on a chip (SoC), system in a package (SiP), antenna in package (AiP), co-packaged optics (CPO), or any combination of the aforementioned devices, but not limited thereto.

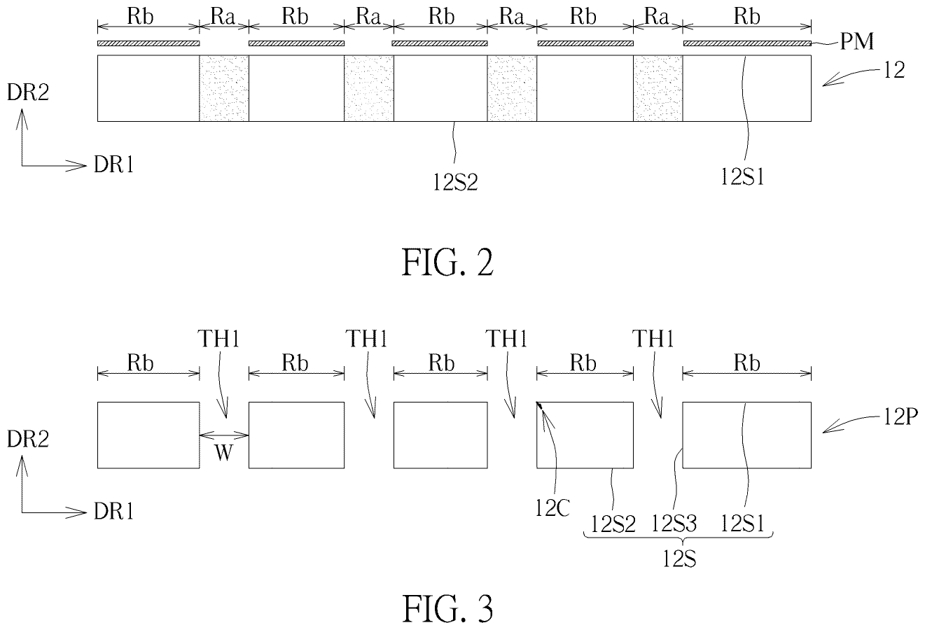

The following figures show a direction DR1 and a direction DR2. The direction DR2 may be a normal direction or a top-view direction of the package device, and as shown in FIG. 2, the direction DR2 may be perpendicular to a top surface 12S1 of a substrate 12. The direction DR1 may be a horizontal direction and may be perpendicular to the direction DR2, and as shown in FIG. 2, the direction DR1 may be parallel to the top surface 12S1 of the substrate 12. The following figures may describe the spatial relations of structures based on the direction DR1 and the direction DR2.

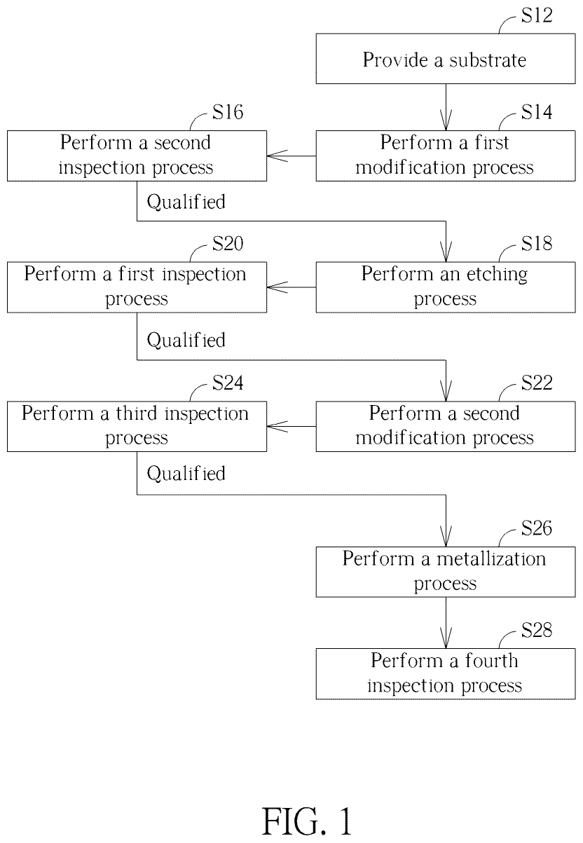

Refer to FIG. 1 to FIG. 7. FIG. 1 schematically illustrates a flow chart of a manufacturing method of a package device according to a first embodiment of the present disclosure, and FIG. 2 to FIG. 7 schematically illustrate structures in different steps of the manufacturing method of the package device according to the first embodiment of the present disclosure. As shown in FIG. 1, a manufacturing method of a package device 1 provided by this embodiment may include step S12 to step S28. In this embodiment, step S12 to step S28 may be performed in sequence, but not limited thereto. The following contents elaborate the manufacturing method of the package device 1 of this embodiment with reference to FIG. 1 to FIG. 7. The manufacturing method of the present disclosure is not limited to the following steps, and other steps may be performed before, after, or during any one of the shown steps.

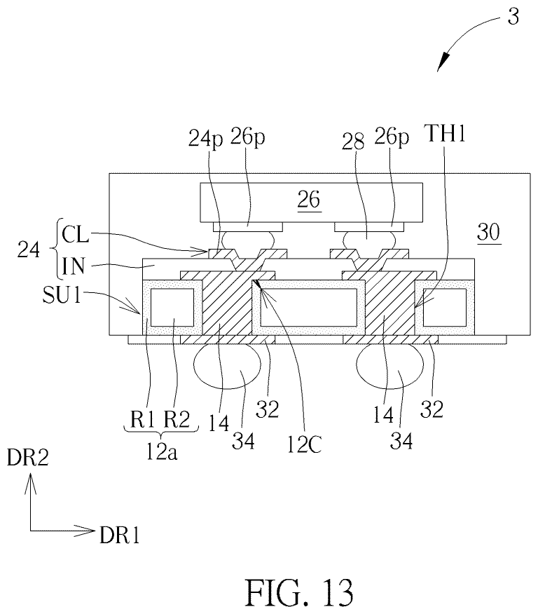

As shown in FIG. 1 and FIG. 2, step S12 is firstly performed to provide a substrate 12. For example, the substrate 12 may include a wafer, a glass, a polymer glass, a transparent material including silicon, an optical layer, an acrylic board, a combination of the aforementioned materials, or other suitable transparent materials, and may have a certain stiffness and insulation. That is, the stiffness of the substrate 12 may be greater than the stiffness of a circuit structure (e.g., a circuit structure 24 of FIG. 13), for example, the stiffness of the substrate 12 may be greater than the stiffness of the insulation layer of the circuit structure, such that when the substrate 12 is used for supporting the circuit structure, warpage may be eased, but not limited thereto. In this embodiment, the substrate 12 takes a glass substrate for example, and the substrate 12 may include silicon dioxide, boron, aluminum, and alkali metal before performing the following steps, but not limited thereto. The alkali metal may be second alkali metal in the following contents, such as sodium or other suitable metal. The term “stiffness” mentioned in this embodiment may be measured through a universal testing machine (UTM). According to some embodiments, a coefficient of thermal expansion of the substrate mentioned in the present disclosure (e.g., the substrate 12 or other substrates in the following contents) may be greater than or equal to 1 ppm/° C. and less than or equal to 10/° C., and the support of the substrate or the reliability of the package device may be enhanced. According to some embodiments, a transmittance of the substrate to visible light mentioned in the present disclosure may at least be greater than or equal to 80%. A size (or an area) of the substrate 12, for example, is like 30 mm*30 mm, 50 mm*50 mm, 700 mm*700 mm or any suitable size, but not limited thereto.

Then, step S14 may proceed to perform a first modification process on the substrate 12. The first modification process may, for example, include a laser irradiation process, or other suitable processes. For example, the substrate 12 may have at least one portion Ra predetermined to form at least one through hole (e.g., through holes TH1 in the following contents), and the first modification process may adjust strength of chemical bonding in the portion Ra of the substrate 12, or may weaken structure strength of the portion Ra to facilitate distinct etching selectivity between the portion Ra and other portion Rb of the substrate 12 to an etchant in the following process. Furthermore, with different materials of the substrate 12, wavelengths of lasers adopted in the laser irradiation process may not be identical, and usually, the absorbance of the substrate 12 to the corresponding wavelength of laser should be greater than or equal to 70%, which will be a suitable wavelength range of the laser. According to some embodiments, when performing the first modification process, a mask PM may be provided between the laser source and the substrate 12 to define the portion Ra predetermined to form the through hole. In some embodiments, the manufacturing method of the package device 1 may selectively not include the mask.

After step S14, step S16 may proceed to perform a second inspection process on the substrate 12 to determine if the structure of the substrate 12 is a qualified product after the first modification process, wherein an inspection criterion of the second inspection process for determining if it is a qualified product may, for example, include judging if the appearance of the substrate 12 or other physical characteristics has a crack, if a size of the crack meets a standard, if the outlines of the substrate 12 meets the predetermined outlines, if the transmittance of the substrate 12 to light (e.g., white light), a haze of the substrate 12, other suitable criteria, or a combination of at least two of the aforementioned criteria meets standards. In some embodiments, the manufacturing method of the package device 1 may alternatively and selectively not perform step S16.

As shown in FIG. 1 and FIG. 3, when the substrate 12 is determined as a qualified product after inspection, or after step S14, step S18 may proceed to perform an etching process on the substrate 12 to remove the portion Ra, such that a patterned substrate 12P is formed, wherein the patterned substrate 12P includes at least one through hole TH1. A plurality of through holes TH1 is taken for example in FIG. 3, but not limited thereto. The etching process may, for example, include a wet etching process using etchant or other suitable processes. According to some embodiments, the etchant may include acid or alkaline liquid, wherein the acid etchant includes hydrofluoric acid, and the alkaline etchant includes sodium hydroxide, but not limited thereto. In some embodiments, in a cross-sectional view, the shape of through hole TH1 may be an hourglass shape, a rectangle, a trapezoid, an inverted-trapezoid, or other suitable shapes. In the figures of the present disclosure, in order to show the through holes TH1, the patterned substrate 12P is shown with a plurality of portions Rb separated, but in reality, the portions Rb may be connected to each other in other positions and are not limited to what is shown in the figures. The etching process mentioned in the present disclosure may, for example, be performed on an upper surface 12S1 or a lower surface 1252 of the substrate 12 to form the through holes TH1, or may be performed simultaneously on the upper surface 12S1 and the lower surface 12S2 of the substrate 12, but not limited thereto.

It is noted that in step S18, since the structure of the patterned substrate 12P is damaged by the etchant, the patterned substrate 12P may have at least one crack 12C after the etching process, but not limited thereto. The crack 12C may, for example, be a micro crack or other types of defect structure. In another embodiment, when the patterned substrate 12P is determined as a disqualified product, the following steps are stopped from proceeding. Specifically, the patterned substrate 12P may have an exposed surface 12S, and the surface 12S may, for example, include the upper surface 12S1, the lower surface 12S2, and a side wall 12S3 of the through hole TH1 of the patterned substrate 12P. The crack 12C may be extended from at least one of the upper surface 12S1, the lower surface 12S2, and the side wall 12S3 of the through hole TH1 toward the interior of the patterned substrate 12P. In some embodiments, the patterned substrate 12P may alternatively not have the crack 12C.

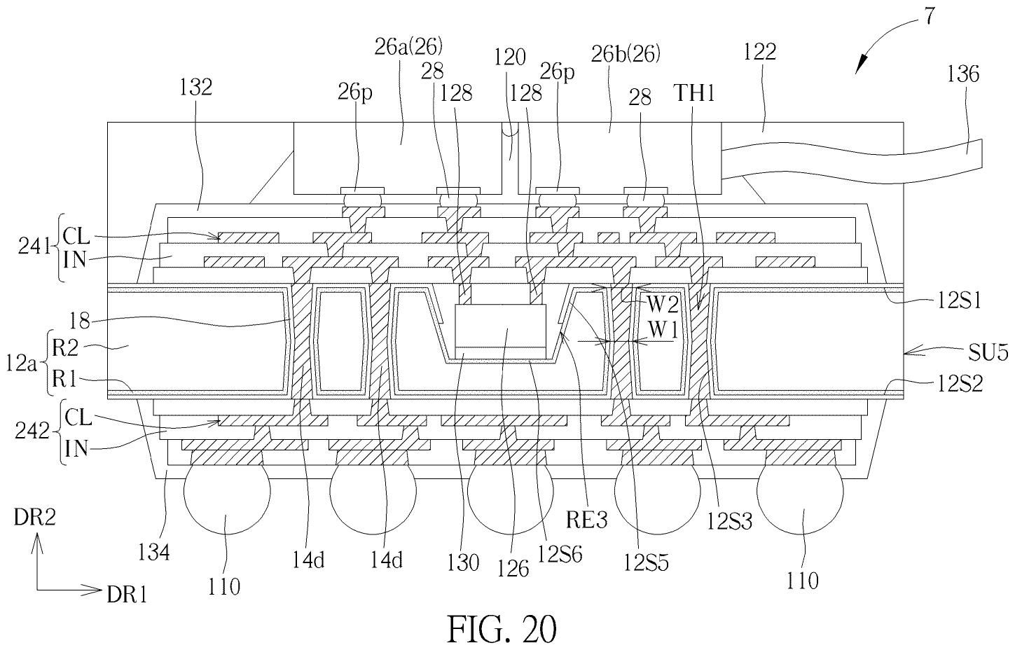

After step S18, step S20 may proceed to perform a first inspection process on the patterned substrate 12P after being etched to determine if the patterned substrate 12P is still a qualified product after the etching process. An inspection criterion of the first inspection process for determining if the patterned substrate 12P is the qualified product may, for example, include judging if a size of the surface crack on the patterned substrate 12P is less than or equal to 5 micrometers, if the surface roughness of the patterned substrate 12P, the side wall roughness of one of the through holes TH1, a width W of one of the through holes TH1, an angle between the side wall 1253 of one of the through holes TH1 and the surface (e.g., the upper surface 12S1 or the lower surface 12S2), and/or the uniformity of the width W of the through hole TH1 meets the standards, other suitable criteria, or a combination of at least two of the aforementioned criteria. When the patterned substrate 12P meets the inspection criterion, the patterned substrate 12P may be determined as a qualified product; and when the patterned substrate 12P does not meet the inspection criterion, the patterned substrate 12P is determined as a disqualified product. For example, when the surface roughness of the patterned substrate 12P is determined not to meet the standards, a surface roughening treatment may be performed on a portion of or a whole of the surface of the patterned substrate 12P to enhance the reliability of the package device 1, but not limited thereto. As disclosed herein, the width of the through hole may be referred to as a width of the through hole along the direction DR1 perpendicular to the normal direction DR2 of the upper surface 12S1. For example, the width W of the through hole TH1 is the width of the through hole along the direction DR1. The uniformity of the width W of the through hole TH1 may, for example, be a ratio of a maximum width of the through hole TH1 to a minimum width of the through hole TH1. For example, as shown in FIG. 20, when the etching process is simultaneously performed on the upper surface 12S1 and the lower surface 12S2 of the substrate 12 to form the through holes TH1, a position of the through hole TH1 corresponding to the minimum width W1 may be at a center of the through hole TH1, such as a position furthest away from the upper surface 12S1 and the lower surface 12S2, and a portion of the through hole TH1 having the maximum width W2 may be located at a position closest to the upper surface 12S1 and/or the lower surface 12S2.

As shown in FIG. 1 and FIG. 4, when the patterned substrate 12P is determined as the qualified product, step S22 may proceed to perform a second modification process on the patterned substrate 12P to form a first portion R1 and a second portion R2 in the patterned substrate 12P. The first portion R1 is closer to the surface 12S than the second portion R2. The first portion R1 may include compressive stress, and the second portion R2 may include tensile stress, such that the strength of the surface 12S of the patterned substrate 12P may be fortified. In other words, since the patterned substrate 12P has not yet suffered a serious damage, and for example, the size of the crack 12C is less than or equal to 5 micrometers, the surface 12S of the patterned substrate 12P may be fortified by the second modification process to reduce the crack 12C from deteriorating or expanding in the following steps, such that a breakage of the patterned substrate 12P is reduced, the reliability of the patterned substrate 12P is enhanced, and/or the yield of the package device 1 is enhanced. The second modification process mentioned herein includes performing the second modification process on a portion of the surface (e.g., a portion of the upper surface 121 and/or a portion of the lower surface 12S2) or a portion of the side wall 12S3 of the patterned substrate 12P, or on the whole surface or the whole side wall 123 of the patterned substrate 12P.

In another embodiment, when the patterned substrate 12P is determined as the disqualified product, and for example the size of the crack 12C is greater than 5 micrometers, the following steps are stopped. That is, since the damage on the patterned substrate 12P is more severe, the seriously damaged patterned substrate 12P is stopped from proceeding to process to prevent the package device formed by the patterned substrate 12P from not meeting the standards.

In an embodiment, the second modification process may include disposing the patterned substrate 12P into a solution, wherein the solution includes a first alkali metal, and the patterned substrate 12P may include a second alkali metal before performing the second modification process, wherein an atomic mass of the first alkali metal may be greater than an atomic mass of the second alkali metal. For example, the second alkali metal includes sodium, and the first alkali metal may include potassium or other alkali metal whose atomic mass is greater than the atomic mass of sodium. Since the activity of the first alkali metal is greater than the activity of the second alkali metal, the first alkali metal ions in the solution may enter the patterned substrate 12P from the surface 12S of the patterned substrate 12P and may replace a portion of the second alkali metal ions in the patterned substrate 12P. Under this condition, a concentration of the first alkali metal (e.g., potassium) of the first portion R1 may be greater than a concentration of the first alkali metal (e. g., potassium) of the second portion R2, or a concentration of the second alkali metal of the second portion R2 may be greater than a concentration of the second alkali metal of the first portion R1. The concentration of the first alkali metal and the concentration of the second alkali metal may, for example, be obtained by an energy-dispersive X-ray spectroscopy (EDX) or SEM in combination with elemental analysis method, but not limited thereto. Since the size of the first alkali metal is greater than the size of the second alkali metal, when the second alkali metal ions in the patterned substrate 12P are replaced with the first alkali metal ions, the first alkali metal ions will provide compressive stress on the patterned substrate 12P, such that the first portion R1 with compressive stress may be formed. In another aspect, the portion of the patterned substrate 12P where the second alkali metal ions are not replaced with the first alkali metal ions may form the second portion R2 with tensile stress compared with the first portion R1. Because the first portion R1 and the second portion R2 present different kinds of stress, stresses inside the patterned substrate 12P may be balanced to strengthen the hardness of the surface 12S, such that the patterned substrate 12P may achieve the effect of fortification. For example, a thickness of the first portion R1 may be less than a thickness of the second portion R2. The thickness of the first portion R1 may, for example, be less than or equal to 5 micrometers. When the thickness of the first portion R1 is too thick, stress of the surface 12S of the patterned substrate 12P may not be balanced by stress of the second portion R2, such that the hardness of the surface 12S of the patterned substrate 12P may not be fortified. Hence, forming the first portion R1 with the thickness in the aforementioned range may give aid to enhancing the hardness of the surface 12S. In this embodiment, the first portion R1 may contact the upper surface 12S1, the lower surface 12S2, the side wall 12S3 of the through hole TH1, and a side surface of the patterned substrate 12P. In the present disclosure, the thickness of the first portion R1 may, for example, be mentioned to as a minimum distance between the surface 12S of the patterned substrate 12P and the second portion R2. It is noted that since the solution may enter into the crack 12C, the surface of the crack 12C may as well form the first portion R1, such that the hardness of the crack 12C may be fortified, and the possibility of the crack 12C further deteriorating or expanding in the following steps may be reduced. According to some embodiments, the concentration of silicon-oxygen of the first portion R1 may be greater than the concentration of the silicon-oxygen of the second portion R2 to enhance the compressive stress of the first portion R1, such that the reliability of the package device 1 is improved, but not limited thereto.

After step S22, step S24 may proceed to perform a third inspection process on the patterned substrate 12P to determine if the structure of the patterned substrate 12P is still a qualified product after the second modification process. For example, an inspection criterion of the third inspection process may include judging if the size of the crack of the surface 12S of the patterned substrate 12P is less than or equal to 5 micrometers, if the concentration of the silicon-oxygen of the patterned substrate 12P meets the standards, if the concentration of alkali metal of the patterned substrate 12P meets the standards, other criteria, or a combination of at least two of the aforementioned criteria. In some embodiments, the manufacturing method of the package device 1 may alternatively and selectively not include step S24.

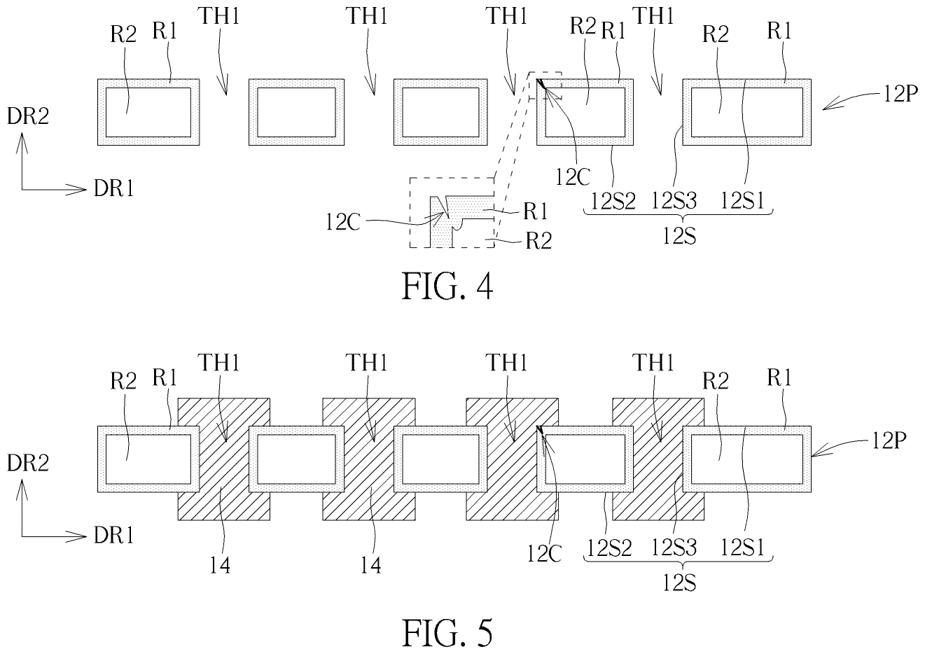

As shown in FIG. 1 and FIG. 5, when the patterned substrate 12P is determined as a qualified product after inspection or after step S22, step S26 may proceed to perform a metallization process on the patterned substrate 12P to form a plurality of conductive elements 14 in the through holes TH1, wherein the first portion R1 may be disposed between the second portion R2 and the conductive elements 14. The conductive element 14 may, for example, include a seed layer and a conductor layer, wherein the seed layer is disposed between patterned substrate 12P and the conductor layer. The metallization process may, for example, include a process of forming the seed layer and a process of forming the conductor layer. The process of forming the seed layer may, for example, include an atomic layer deposition (ALD) process, a physical vapor deposition (PVD) process, a chemical vapor deposition (CVD) process, a sputtering process, a coating process, other suitable deposition processes, or a combination of the aforementioned processes. The process of forming the conductor layer may, for example, include an electroplating process, an electroless plating process, a PVD process, a CVD process, a sputtering process, a coating process, other suitable deposition processes, or a combination of the aforementioned processes. In another embodiment, when the patterned substrate 12P is determined as a disqualified product, and for example, the size of the crack 12C is greater than 5 micrometers, the following steps are halted.

After step S26, step S28 may selectively proceed to further perform a fourth inspection process on the patterned substrate 12P to determine if the structure of the patterned substrate 12P is qualified after the metallization process. For example, an inspection criterion of the fourth inspection process may include judging if the appearances of the surface 12S of the patterned substrate 12P and the conductive elements 14 or other physical characteristics meet the requirements, performing a conductivity test on the conductive elements 14, other inspection criteria, or a combination of at least two of the aforementioned criteria. In some embodiments, the manufacturing method of the package device 1 may alternatively and selectively not include step S28.

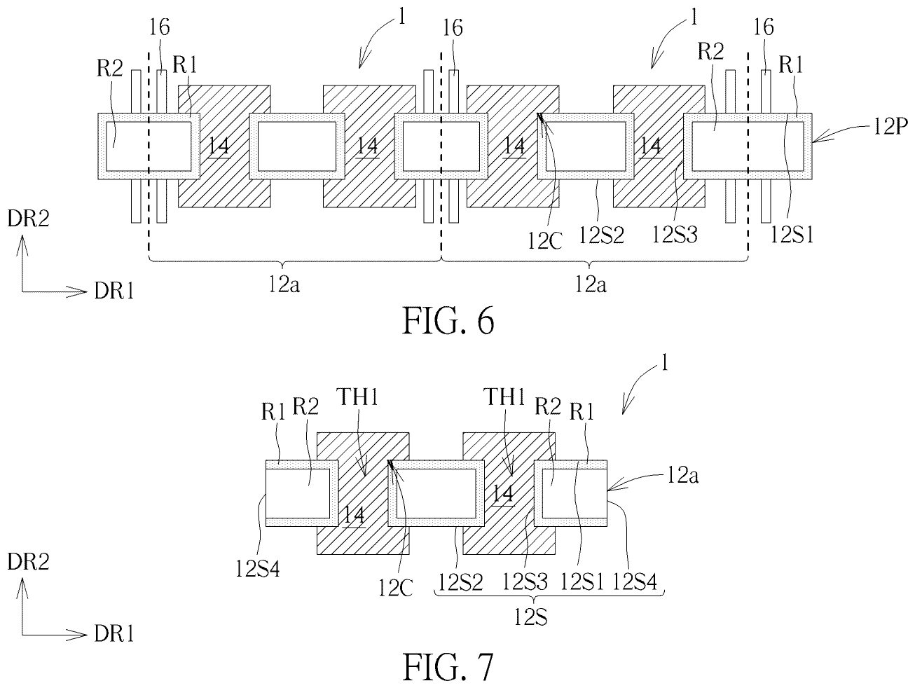

As shown in FIG. 6, after step S28, a cutting process may selectively be performed on the strengthened patterned substrate 12P to form at least one package device 1 of this embodiment, but not limited thereto. In the embodiment of FIG. 6, the cutting process may, for example, cut the patterned substrate 12P into a plurality of unit substrates 12a to form a plurality of package devices 1. In other words, each of the package devices 1 may include one unit substrate 12a used as a substrate structure unit. In the appended claims, the unit substrate 12a may also be mentioned to as a substrate. When the unit substrate 12a includes glass, the package device 1 of FIG. 7 may, for example, be a through glass via (TGV) substrate, but not limited thereto. The cutting process may, for example, include a laser cutting process, a blade cutting process, other suitable processes, or any combination of the aforementioned processes. In some embodiments, the cutting process may include disposing an anti-explosive film 16 on the upper surface 12S1 and the lower surface 12S2 of the patterned substrate 12P. It is noted that during the cutting process, the upper surface 12S1 and the lower surface 12S2 of the patterned substrate 12P may withstand normal forces perpendicular to the upper surface 12S1 and the lower surface 12S2, for example, forces acting along the direction DR2 and a direction opposite to the direction DR2. By disposing the anti-explosive film 16, the possibility of producing breakages or explosion of the patterned substrate 12P after withstanding the normal forces may be reduced.

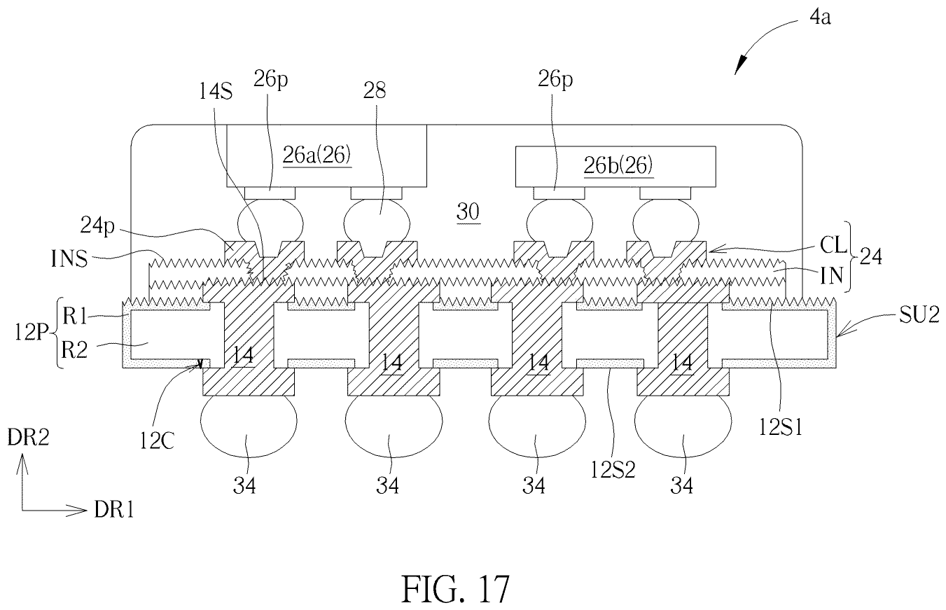

As shown in FIG. 7, after the package device 1 is formed, the anti-explosive film 16 may be removed. Since the unit substrate 12a of this embodiment is formed by the cutting process after the second modification process, a side surface 12S4 of the unit substrate 12a may expose the second portion R2, but the present disclosure is not limited thereto. In some embodiments, the package device 1 may further include a circuit structure, an electronic unit, and/or other suitable elements disposed on the conductive elements 14 and the unit substrate 12a. The circuit structure may, for example, be a redistribution structure. In this case, the circuit structure, the electronic unit, and/or other suitable elements may be formed on the conductive elements 14 and the unit substrate 12a after the cutting process, or may be formed on the conductive elements 14 and the substrate 12 between the metallization process and the cutting process. The circuit structure and the electronic unit may, for example, be respectively identical to a circuit structure 24 and an electronic unit 26 of FIG. 13, and FIG. 17 to FIG. 19 in the following contents, but not limited thereto.

As shown in FIG. 7, the package device 1 provided by this embodiment may include the unit substrate 12a and the conductive elements 14, and the unit substrate 12a may include the first portion R1 and the second portion R2, wherein the thickness of the first portion R1 may be less than the thickness of the second portion R2. The first portion R1 includes compressive stress, the second portion R2 includes tensile stress, and the first portion R1 is closer to the surface 12S of the unit substrate 12a than the second portion R2. Therefore, when the following step of forming the circuit structure or other thermal processes is performed on the unit substrate 12a under the condition that the unit substrate 12a has the crack 12C, the possibility of the crack 12C deteriorating or size of the crack 12C expanding may be reduced, such that the yield or reliability of the product is enhanced. Besides, since the unit substrate 12a includes the through holes TH1 penetrating the first portion R1 and the second portion R2, and the conductive elements 14 are disposed in the through holes TH1, an element disposed on the upper surface 12S1 of the unit substrate 12a may be electrically connected to another element disposed on the lower surface 12S2 of the unit substrate 12a through the unit substrate 12a, such that the effect of the conductive via is achieved.

It is noted that a weight percentage of the second alkali metal in the second portion R2 may be less than or equal to 10 wt %, for example, may be less than or equal to 5 wt % or 3 wt %, and hence, a weight percentage of the first alkali metal replacing the second alkali metal in the first portion R1 may be reduced, such that a dissipation factor (Df) of the unit substrate 12a may be reduced. When one of the conductive elements 14 transmits a signal, transportation carriers mainly move along the conductive element 14 near the surface 12S of the unit substrate 12a. Hence, if the dissipation factor of the unit substrate 12a is too large, serious transmission losses may be generated. By controlling the weight percentage of the second alkali metal in the second portion R2 in the aforementioned range, the dissipation factor of the unit substrate 12a may be reduced to lighten the effect on signal transmission and especially to effectively reduce the effect on high-frequency signal transmission. The weight percentage of the second alkali metal in the second portion R2 may, for example, be obtained by taking a sample with certain weight from the substrate 12 to perform measurement, but not limited thereto. The dissipation factor mentioned in the present disclosure may be obtained using IPC-TM-650 2.5.5.15 standard measurement method or IPC-TM-650 2.5.5.13 standard measurement method to perform tests under different frequencies.

The package device and the manufacturing method thereof are not limited to the above-mentioned embodiments and may have other embodiments. To simplify description, different embodiments in the following contents will use the same notations to the same elements from the first embodiment. To clearly clarify different embodiments, the following contents will emphasize on the difference between different embodiments and the above-mentioned embodiments, and will not further elaborate for the repeated part.

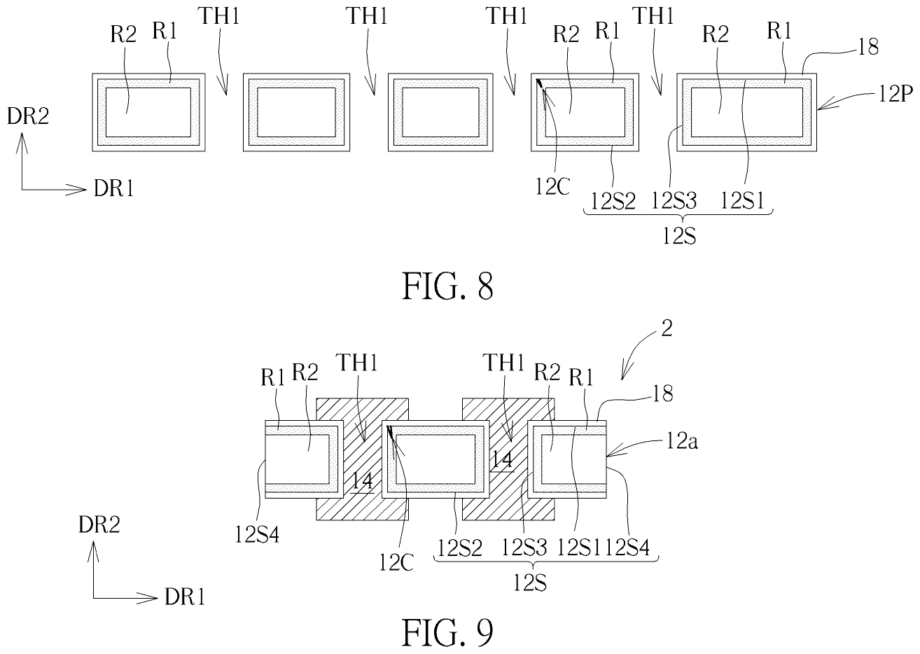

Refer to FIG. 8 to FIG. 9. FIG. 8 to FIG. 9 schematically illustrate structures in different steps of a manufacturing method of a package device according to a second embodiment of the present disclosure. As shown in FIG. 8 to FIG. 9, the manufacturing method of the package device 2 provided by this embodiment further includes forming a buffer layer 18 on the surface 12S of the patterned substrate 12P between the second modification process and the metallization process. In the manufacturing method of this embodiment, steps before the step of forming the buffer layer 18 may be similar or identical to the aforementioned embodiment of FIG. 2 to FIG. 4, which may be referred to the above-mentioned contents, and they will not be redundantly detailed herein.

Specifically, as shown in FIG. 8, after the second modification process is performed on the patterned substrate 12P or after step S24, the buffer layer 18 may be formed on the surface 12S of the patterned substrate 12P. In this embodiment, the buffer layer 18 may cover the upper surface 12S1, the lower surface 12S2, and the side walls 123 of the through holes TH1. The method of forming the buffer layer 18 may include a disposition process or other suitable processes. The disposition process may, for example, include a coating process, an evaporation process, an ALD process, other physical disposition processes, or other chemical disposition processes. The buffer layer 18 may include an organic or an inorganic material. For example, the buffer layer 18 may include polyimide (PI), poly-p-xylylene (Parylene), benzocyclobutene (BCB), epoxy, polycarbonate (PC), polyethylene terephthalate (PET), polyethylene naphthalate (PEN), or other suitable materials, but not limited thereto.

It is worth noting that the dissipation factor of the buffer layer 18 may be less than the dissipation factor of the first portion R1. For example, the dissipation factor of the buffer layer 18 may be less than 0.1 as the operation frequency is greater than or equal to 10 million hertz (MHz). When one of the conductive elements 14 in one of the through holes TH1 transmits a signal, the transportation carriers mainly move along the surface of the conductive element 14 near the buffer layer 18. Hence, if the dissipation factor of the buffer layer 18 is too large, serious transmission losses may be generated. By controlling the dissipation factor of the buffer layer 18 in the range of less than 0.1, the effect of the buffer layer 18 on signal transmission may be reduced, and especially, the effect on transmitting high-frequency signal may be effectively reduced.

As shown in FIG. 9, after the buffer layer 18 is formed, the metallization process may proceed to form the conductive elements 14 in the through holes TH1. Then, the cutting process may be performed on the substrate 12, such that the package device 2 of this embodiment is formed. Since the metallization process and the cutting process of the manufacturing method of this embodiment may be similar or identical to the aforementioned embodiments, which may be referred to the above-mentioned contents, and they will not be detailed redundantly herein. In some embodiments, since the buffer layer 18 is formed on the patterned substrate 12P, the anti-explosive film 16 of FIG. 6 may be optionally disposed or not disposed on the patterned substrate 12P during cutting the patterned substrate 12P. In some embodiments, the fourth inspection process may be performed selectively after the metallization process, but not limited thereto. In some embodiments, the buffer layer 18 of FIG. 9 may alternatively be applied to the package device of any embodiment in the following contents, but not limited thereto.

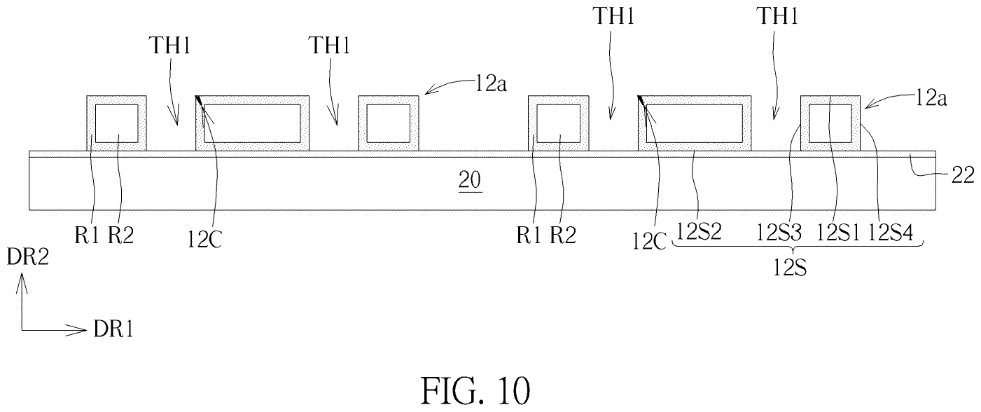

Refer to FIG. 10 to FIG. 13. FIG. 10 to FIG. 13 schematically illustrate structures in different steps of a manufacturing method of a package device according to a third embodiment of the present disclosure. As shown in FIG. 10, the manufacturing method of the package device 3 provided by this embodiment may perform a cutting process between step S20 of the first inspection process and the step S22 of the second modification process to form at least one unit substrate 12a, and then, the second modification process is performed on the unit substrate 12a to form the first portion R1 and the second portion R2 in the unit substrate 12a. Since the cutting process is performed before the second modification process, the first portion R1 including compressive stress may not need to withstand the normal forces, such that the probability of damaging the unit substrate 12a may be reduced. In this embodiment, the first portion R1 may be adjacent to every surfaces of the unit substrate 12a, such as the upper surface 12S1, the lower surface 12S2, the side walls 12S3 of the through holes TH1, and the side surface 1284, such that the second portion R2 may be surrounded by the first portion R1, but not limited thereto. In the manufacturing method of this embodiment, steps before the cutting process may be similar or identical to the aforementioned embodiment of FIG. 2 and FIG. 3, which may be referred to the above-mentioned embodiments, and they will not be redundantly detailed herein.

After the second modification process, the at least one unit substrate 12a may be disposed on a carrier 20. FIG. 10 takes a plurality of unit substrates 12a disposed on the carrier for example, but not limited thereto. In the embodiment of FIG. 10, before disposing the unit substrates 12a, a seed layer 22 may be formed on the carrier 20 to give aid to the following metallization process. In some embodiments, before forming the seed layer 22, a release layer may be further selectively formed on the carrier 20. In some embodiments, before forming the release layer, an anti-warpage layer may be further selectively formed on the carrier 20.

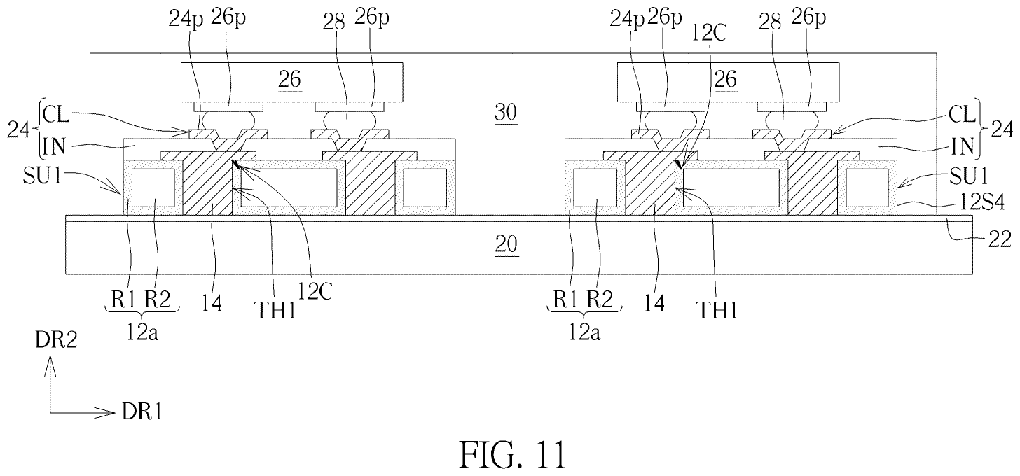

As shown in FIG. 11, after the unit substrates 12a are disposed on the carrier 20, the metallization process proceeds to form the conductive elements 14 in the through holes TH1 of the unit substrates 12a, wherein portions of the conductive elements 14 may be disposed on the upper surfaces 12S1 of the unit substrates 12a, but not limited thereto. For example, during the metallization process, a patterned photo resist layer may, in advance, be formed on the unit substrates 12a to shield portions of the unit substrates 12a and the carrier 20 that are not intended to form the conductive elements 14, and the patterned photo resist layer exposes the through holes TH1 of the unit substrates 12a. Then, the conductive elements 14 are formed in the through holes TH1 and on portions of the upper surfaces 12S1 of the unit substrates 12a. Afterwards, the patterned photo resist layer is removed. The metallization process may be identical to the metallization process of the embodiment of FIG. 5, which may be referred to the above-mentioned contents, and it is not redundantly detailed herein.

After the metallization process, a circuit structure 24 may be formed on each unit substrate 12a. The circuit structure 24 may include at least one conductive layer CL and at least one insulation layer IN, such that wirings are redistributed, and/or fan-out area of the wirings is further increased, or such that different electronic units may be electrically connected through the circuit structure. Alternatively, the circuit structure may be a substrate used as an electrical interface routing between a wiring and another wiring. The objective of the circuit structure is to expand the connection to have broader spacing or to redistribute the connection to another connection with different spacings. In other words, the circuit structure herein may alternatively be a redistribution layer/structure. The circuit structure mentioned here or in the following contents may be electrically connected to each chip or electronic unit through the connection elements or other bonding elements. Step of forming the circuit structure 24 may include a thermal process, such as a disposition process, an oxidation process, an annealing process, a surface treatment process, or other suitable processes.

The circuit structure 24 of FIG. 11 takes one conductive layer CL and one insulation layer IN for example, but not limited thereto. In some embodiments, the circuit structure 24 may include a plurality of conductive layers CL and a plurality of insulation layers IN. In FIG. 11, the conductive layer CL may include a plurality of bonding pads 24p, the insulation layer IN may include a plurality of through holes, and the bonding pads 24p may be electrically connected to the corresponding conductive elements 14 through the through holes, but not limited thereto. For example, the insulation layer IN may include polyimide (PI), photosensitive polyimide (PSPI), Ajinomoto build-up film (ABF), silicon oxide (SiOx), silicon nitride (SiNx), silicon oxynitride (SiOxNy), or other suitable dielectric materials. The conductive layer CL may include a conductive material, and the conductive material includes copper (Cu), titanium (Ti), aluminum (Al), molybdenum (Mo), nickel (Ni), ruthenium (Ru), tantalum (Ta), tungsten (W), nitride, carbide, other conductive materials, or any combination of the aforementioned materials, but not limited thereto. In some embodiments, numbers and wiring layout of the conductive layer CL and the insulation layer IN of the circuit structure 24 may be adjusted according to needs. The term “surface treatment process” mentioned herein refer to when layers are formed sequentially along a top view direction of the package device (the direction DR2), and an element B is stacked, formed, or disposed on an element A, step of surface roughening treatment is performed on the element A to enhance the bonding strength between the element A and the element B, wherein the element A and the element B may include the same material or different materials. For example, before forming the circuit structures 24 on the unit substrates 12a or on the patterned substrate, step of surface roughening treatment may be performed on the surfaces of the unit substrates 12a or the patterned substrate. Or, during alternately forming the conductive layers CL and the insulation layers IN stacked in turn, step of surface roughening treatment may be performed on the surface of the conductive layer CL and/or the surface of the insulation layer IN. The method of performing surface roughening treatment may include a laser irradiation process, a wet etching process, a dry etching process, a plasma treatment process, a transfer printing process, or a combination of the above-mentioned processes, but not limited thereto. In some embodiments, the surface treatment process may be applied to the surface of any one of the unit substrate, the patterned substrate, and the conductive layer and the insulation layer of the circuit structure, but not limited thereto.

Following up, an electronic unit 26 may be disposed on and bonded to the bonding pads 24p of the circuit structure 24. For example, the electronic unit 26 may be bonded to the bonding pads 24p through connection elements 28, such that bonding pads 26p of the electronic unit 26 may respectively be electrically connected to the bonding pads 24p of the circuit structure 24 through the connection elements 28, but not limited thereto. The connection elements 28 may, for example, include tin ball, nickel, gold, copper, gallium, or other suitable conductive materials. The electronic unit 26 may include a chip, a chip packaged structure, a chip assembled structure, or other types of element structure. The chip may have an active surface and a rear surface, wherein a surface of the chip having the bonding pads 26p may, for example, be the active surface used to be bonded with the connection elements, and a surface of the chip opposite to the active surface is the rear surface. It should be understood that the bonding pads 26p may be signal input/output pads (I/O pad) of the electronic unit 26, and the bonding pads 26p may, for example, include aluminum, nickel, gold, copper, nitride, or other suitable conductive materials.

Afterwards, a package process proceeds to form a protection layer 30 on the electronic units 26, the circuit structures 24, and the carrier 20. The package process may, for example, include a molding process or other suitable processes. In some embodiments, the package process may, for example, include a thermal process. The protection layer 30 may include a package material or other suitable materials. The package material may, for example, include epoxy molding compound (EMC) or other suitable organic materials. The protection layer 30 may at least surround the electronic unit 26. In the present disclosure, an element “surrounds” another element may refer to in the cross-sectional view of the package device, the element at least contacts a side surface of the another element. In the embodiment of FIG. 11, the protection layer 30 may contact the unit substrates 12a, for example, the protection layer 30 may be extended to the side surfaces 12S4 of the unit substrates 12a to protect the side surfaces 1254 of the unit substrates 12a. In some embodiment, a portion of the protection layer 30 on the rear surfaces of the electronic units 26 may further be selectively removed, but not limited thereto. Step of removing the portion of the protection layer 30 on the electronic units 26 may include a grinding process or other suitable processes.

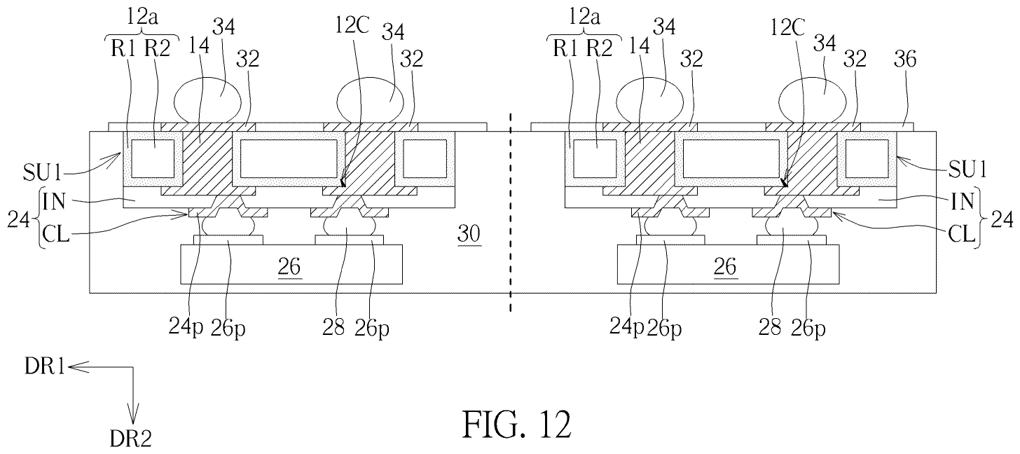

As shown in FIG. 12, after the protection layer 30 is formed or after the portion of the protection layer 30 is removed, the carrier 20 and the seed layer 22 may be removed to expose the lower surface 12S2 of the unit substrates 12a and lower surfaces of the conductive elements 14. Afterwards, the unit substrates 12a and the protection layer 30 are flipped upside down, and bonding pads 32 may be formed on the lower surfaces of the conductive elements 14. Then, connection elements 34 are formed on the bonding pads 32, such that a plurality of substrate structure units SU1 each including the unit substrate 12a, the conductive elements 14, and the connection elements 34. The connection element 34 may be similar or identical to the connection element 28, and hence, it is not detailed redundantly herein. In some embodiments, a solder resist layer 36 may be selectively formed on the lower surfaces 1252 of the unit substrates 12a and the surface of the protection layer 30 to protect the unit substrates 12a, but not limited thereto. Step of forming the solder resist layer 36 may be performed between forming the bonding pads 32 and forming the connection elements 34 or may be performed before forming the connection elements 34. In some embodiments, the solder resist layer 36 may alternatively be replaced with an insulation layer, but not limited thereto. Or, steps of forming the bonding pads 32 and forming the solder resist layer 36 may alternatively be replaced with forming another circuit structure.

As shown in FIG. 13, after forming the connection elements 34, another cutting process may be performed to form the package device 3 of this embodiment. In this embodiment, the cutting process may, for example, separate portions of the protective layer 30 corresponding to the different unit substrates 12a, but not limited thereto.

In the embodiment of FIG. 13, a difference between the package device 3 and the package device of the aforementioned embodiments is that the package device 3 may further include the circuit structure 24 and the connection elements 34 respectively disposed on the upper surface 12S1 and the lower surface 12S2 of the unit substrate 12a, and the circuit structure 24 may be electrically connected to the connection elements 34 through the conductive elements 14. That is, the unit substrate 12a is disposed between the circuit structure 24 and the connection elements 34. In some embodiments, the package device 3 may further include the electronic unit 26 and the protection layer 30, wherein the electronic unit 26 is disposed on the circuit structure, and the protection layer 30 surrounds the electronic unit 26, but not limited thereto.

Refer to FIG. 14 to FIG. 16. FIG. 14 to FIG. 16 schematically illustrate structures in different steps of a manufacturing method of a package device according to a fourth embodiment of the present disclosure. As shown in FIG. 14, in the manufacturing method of the package device 4 provided by this embodiment, the metallization process is performed before the second modification process. Specifically, the conductive elements 14 may be formed in the through holes TH1 between step of forming the through holes TH1 and performing the second modification process. In the manufacturing method of this embodiment, steps before performing the metallization process may be similar or identical to the above-mentioned embodiment of FIG. 2 and FIG. 3, and the metallization process may be identical to the metallization process of the aforementioned embodiments, which may be referred to the above-mentioned contents, and they will not be detailed redundantly herein.

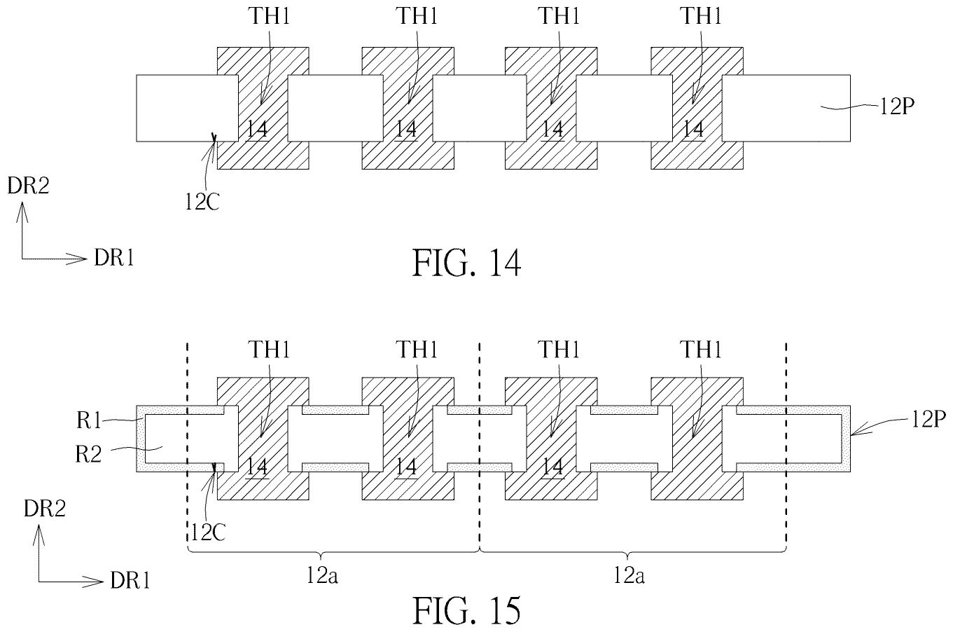

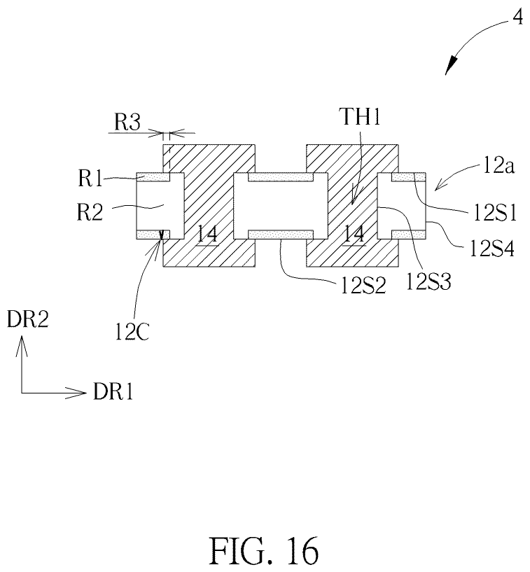

As shown in FIG. 15, after forming the conductive elements 14, the second modification process may proceed to form the first portion R1 and the second portion R2 in the patterned substrate 12P. Since the second modification process is performed after the conductive elements 14 are formed, the first alkali metal ions enter the patterned substrate 12P through a surface of the patterned substrate 12P not overlapped with the conductive elements 14. Accordingly, the first portion R1 may be adjacent to and may contact an exposed surface of the patterned substrate 12P, such as a portion of the upper surface 12S1 and a portion of the lower surface 12S2. Since the first alkali metal ions in the first portion R1 may have a diffusion phenomenon, the formed first portion R1 and the conductive elements 14 may have at least one overlapped portion R3 in the top view direction of the package device 4 (e.g., the direction DR2), as shown in FIG. 16. In this embodiment, since the first portion R1 is not formed on the side wall 1253, an effect of the first portion R1 on transmission loss of signal transmitted by the conductive elements 14 may be reduced. In some embodiments, after the second modification process, the third inspection process may be selectively performed such as step S24 of FIG. 1, which may be referred to the aforementioned contents, and it will not be detailed redundantly herein.

As shown in FIG. 15 and FIG. 16, after the second modification process or the third inspection process, the cutting process may be performed on the strengthened substrate 12 to form at least one package device 4. The cutting process of this embodiment may be similar or identical to any one of the above-mentioned embodiments, which may be referred to the aforementioned contents, and it will not be detailed redundantly herein.

Refer to FIG. 17. FIG. 17 schematically illustrates a cross-sectional view of a package device according to a modified embodiment of the fourth embodiment of the present disclosure. A difference between the package device 4a provided by this modified embodiment and the package device 4 of FIG. 16 is that the package device 4a may further include the circuit structure 24, at least one electronic unit 26, and the protection layer 30. In this modified embodiment, the package device 4a may selectively not perform the cutting process, and hence, the substrate structure unit SU2 may include the patterned substrate 12P and the plurality of conductive elements 14. In addition, after the second modification process or the third inspection process, the circuit structure 24 is formed on the substrate structure unit SU2. Then, the electronic unit 26 is disposed on the circuit structure 24, and the protection layer 30 is formed on the circuit structure 24 and the patterned substrate 12P. In some embodiments, the substrate structure unit SU2 may alternatively be replaced with the package device 4 of FIG. 16, and that is, the circuit structure 24, the electronic unit 26, and the protection layer 30 may be sequentially formed on the package device 4 of FIG. 16.

In this embodiment, the method of forming the package device 4a may include the aforementioned surface treatment process, but not limited thereto. For example, after the metallization process of forming the conductive elements 14, step of surface roughening treatment may be performed on the upper surface 12S1 of the patterned substrate 12P and/or surfaces 14S of the conductive elements 14; and/or in step of forming the conductive layers CL and/or the insulation layers IN of the circuit structure 24, step of surface roughening treatment may be performed on a surface of the conductive layer CL and/or a surface INS of the insulation layer IN to enhance the bonding strength between the insulation layer IN and the patterned substrate 12P, the bonding strength between the insulation layers IN, the bonding strength between the insulation layer IN and the conductive layer CL, and the bonding strength between the conductive layers CL. For example, the upper surface 12S1 of the patterned substrate 12P, the surfaces 14S of the conductive elements 14, and the surface INS of the insulation layer IN may be rough surfaces.

As shown in FIG. 17, after the protection layer 30 is formed, the connection elements 34 may be further formed under the conductive elements 14. In some embodiments, the solder resist layer 36 of FIG. 13 may alternatively be selectively formed on the lower surface 12S2 of the patterned substrate 12P before or after the connection elements 34 are formed, but not limited thereto.

In some embodiments, the package device 4a may selectively include a plurality of electronic units 26, such as including an electronic unit 26a and an electronic unit 26b. The electronic unit 26a and the electronic unit 26b may have different thicknesses, and the rear surface of the electronic unit 26a may be exposed while the protection layer 30 may be disposed on the rear surface of the electronic unit 26b, but not limited thereto. The functions of the electronic unit 26a and the electronic unit 26b may be adjusted based on needs, for example, having different functions. In some embodiments, the substrate structure unit SU2 of FIG. 17 may alternatively be replaced with the package device 1 of FIG. 7, the package device 2 of FIG. 9, or the substrate structure unit SU1 of FIG. 13.

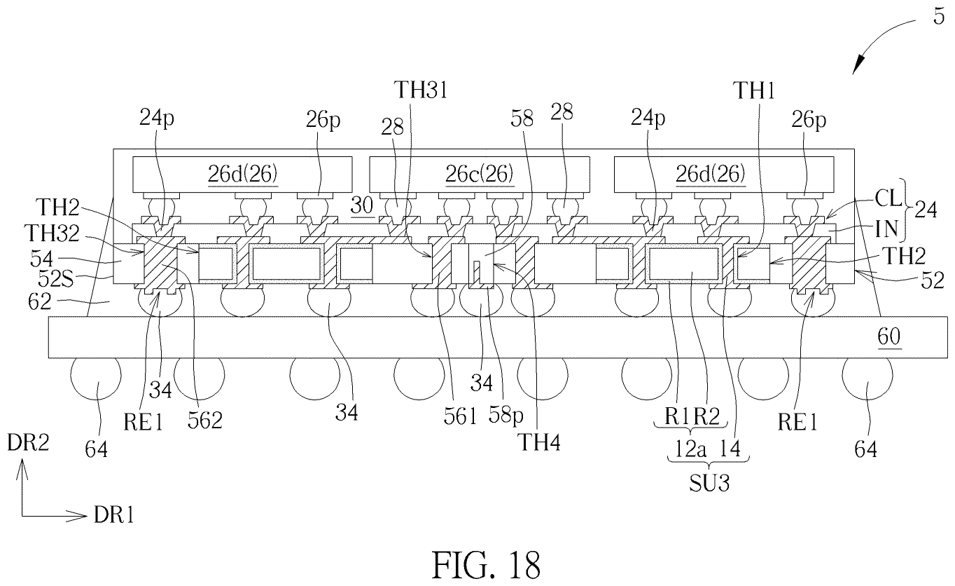

Refer to FIG. 18. FIG. 18 schematically illustrates a cross-sectional view of a package device according to a fifth embodiment of the present disclosure. As shown in FIG. 18, the package device 5 provided by this embodiment may include at least one substrate structure unit SU3 disposed in a core substrate 52. The substrate structure unit SU3 of this embodiment may, for example, be similar or identical to the package device 1 of FIG. 7, which may be referred to the aforementioned contents, and it will not be detailed redundantly herein. In some embodiments, the substrate structure unit SU3 may alternatively be replaced with the package device 2 of FIG. 9, the substrate structure unit SU1 of FIG. 13, the package device 4 of FIG. 16, or the substrate structure unit SU2 of FIG. 17, but not limited thereto.

Specifically, the package device 5 may include a core substrate 52, and the core substrate 52 may include a plurality of substrate structure units SU3 and a supporting member 54. In this embodiment, the supporting member 54 may, for example, include a rigid substrate, and the supporting member 54 may include a plurality of through holes TH2 used to dispose the substrate structure units SU3, wherein the core substrate 52 may further include an adhesive layer or a buffer material disposed between the supporting member 54 and the substrate structure units SU3 and used to attach the supporting member 54 and the substrate structure units SU3 or mitigate the collision between the supporting member 54 and the substrate structure units SU3, but not limited thereto. It is noted that a coefficient of thermal expansion of the supporting member 54 may be close or identical to a coefficient of thermal expansion of the unit substrate 12a of the substrate structure unit SU3, for example the supporting member 54 and the unit substrate 12a may include identical material, such as glass. Under this circumstance, warpage produced by the core substrate 52 under vast change in temperature may be reduced. In some embodiments, the coefficient of thermal expansion of the supporting member 54 may be between 0.5 ppm/° C. and 15 ppm/° C., and the coefficient of thermal expansion of the unit substrate 12a may be between 1 ppm/° C. and 10 ppm/° C.

In some embodiments, the supporting member 54 may further include at least one through hole TH31 disposed between two adjacent substrate structure units SU3, and the core substrate 52 may further include at least one conductive element 561 disposed in the through hole TH31. In some embodiments, a width of the through hole TH31 may, for example, be greater than a width of the through hole TH1 of the unit substrate 12a. In some embodiments, the supporting member 54 may further include at least one through hole TH4, and the package device 5 may further include at least another electronic unit 58 disposed between the two adjacent substrate structure units SU3, and the electronic unit 58 may be surrounded by the supporting member 54. The electronic unit 58 may include an active element or a passive element disposed in the through hole TH4. For example, two of the plurality of the electronic units 26 may be electrically connected to each other through the electronic unit 58, and the electronic unit 58 may be used as a bridge or an interposer for electrically connecting the electronic units 26 to each other. The passive element may, for example, include a resistor, a capacitor, an inductor, or other suitable elements. In some embodiments, a bonding pad 58p of the electronic unit 58 may be disposed on a surface of the electronic unit 58 away from or adjacent to the electronic units 26, but not limited thereto. The core substrate 52 may further include an adhesive layer disposed between the supporting member 54 and the electronic unit 58, and the adhesive layer is used to attach the electronic unit 58 to the supporting member 54, but not limited thereto. In FIG. 18, for clearly illustrating the supporting member 54, the substrate structure units SU3, and the electronic unit 58 of the core substrate 52, the adhesive layer of the core substrate 52 is neglected, but not limited thereto. In some embodiments, the connection elements 34 may respectively be disposed on the lower surfaces of the conductive elements 14, the conductive element 561, and the bonding pads 58p.

In some embodiments, the supporting member 54 may further include at least one through hole TH32 disposed between the substrate structure unit SU3 and a side surface 52S of the core substrate 52. In other words, the through hole TH32 may be closer to the side surface 52S of the core substrate 52 than the substrate structure unit SU3. In addition, the core substrate 52 may further include at least one conductive element 562 disposed in the through hole TH32. In other words, the conductive element 562 is adjacent to the side surface 52S of the core substrate 52. A width of the through hole TH32 may, for example, be greater than the width of the through hole TH31 and the width of the through hole TH1. In some embodiments, the connection element 34 may be disposed on a lower surface of the conductive element 562. It is noted that the lower surface of the conductive element 562, which is adjacent to the side surface 52S of the core substrate 52, away from the electronic unit 26 may have a trench RE1 to reduce stress on the core substrate 52 adjacent to the side surface 52S. Or, the trench RE1 may alternatively enhance contact area of the connection element 34 with the corresponding conductive element 562, such that the bonding strength is enhanced.

In some embodiments, the supporting member 54 may include silicon oxide, silicon nitride, silicon oxynitride, epoxy, other suitable package materials, or a combination of the aforementioned materials, and the supporting member 54 may surround the unit substrates 12a of the substrate structure unit SU3. The package material may, for example, include EMC, PSPI, or other suitable organic materials. In this case, the supporting member 54 may directly contact the side wall of the unit substrate 12a and the side wall of the electronic unit 58. In the manufacturing method of the packaged device according to some embodiments, the substrate structure units SU3 and the electronic unit 58 may be disposed on a carrier, and then, a packaging process is performed to form the package material on the substrate structure units SU3, the electronic unit 58, and the carrier. Afterwards, the package material disposed on the substrate structure units SU3 and the electronic unit 58 is removed to form the supporting member 54, but not limited thereto.

The package device 5 may further include the circuit structure 24 and the plurality of electronic units 26. The circuit structure 24 is disposed on the core substrate 52, and the electronic units 26 are disposed on the circuit structure 24. The electronic units 26 may be electrically connected to the conductive elements 14, the conductive element 561, and the conductive element 562 of the core substrate 52 through the circuit structure 24. In some embodiments, the electronic units 26 may be electrically connected to each other through the circuit structure 24, but not limited thereto. In some embodiments, the electronic units 26 may be electrically connected to the electronic unit 58 through the circuit structure 24, but not limited thereto.

In FIG. 18, the electronic units 26 may, for example, include at least one electronic unit 26c and at least one electronic unit 26d, and the electronic unit 26c and the electronic unit 26d may respectively have different functions. For example, the electronic unit 26c may be a control chip, and the electronic unit 26d may be a memory chip such as a high bandwidth memory (HBM) chip.

As shown in FIG. 18, the package device 5 may further include the protection layer 30 disposed on the circuit structure 24 and surrounding the electronic units 26. The protection layer 30 may be extended to the side surface of the circuit structure 24 and may be used to protect the circuit structure 24. The protection layer 30 may be identical to the aforementioned embodiments, which may be referred to the aforementioned contents, and it will not be detailed redundantly herein.

Besides, the package device 5 may further optionally include a circuit carrier 60, and the core substrate 52 may be bonded to the circuit carrier 60 through the corresponding connection elements 34, such that the electronic units 26 may be electrically connected to the circuit carrier 60. In some embodiments, the package device 5 may further optionally include an adhesive layer 62 disposed between the core substrate 52 and the circuit carrier 60, and the adhesive layer 62 is used to enhance the bonding strength between the core substrate 52 and the circuit carrier 60. The adhesive layer 62 may, for example, include an underfill material or other suitable materials. In some embodiments, the package device 5 may further include a plurality of connection elements 64 disposed under the circuit carrier 60, and the connection elements 64 are used to be bonded and electrically connected to other elements.

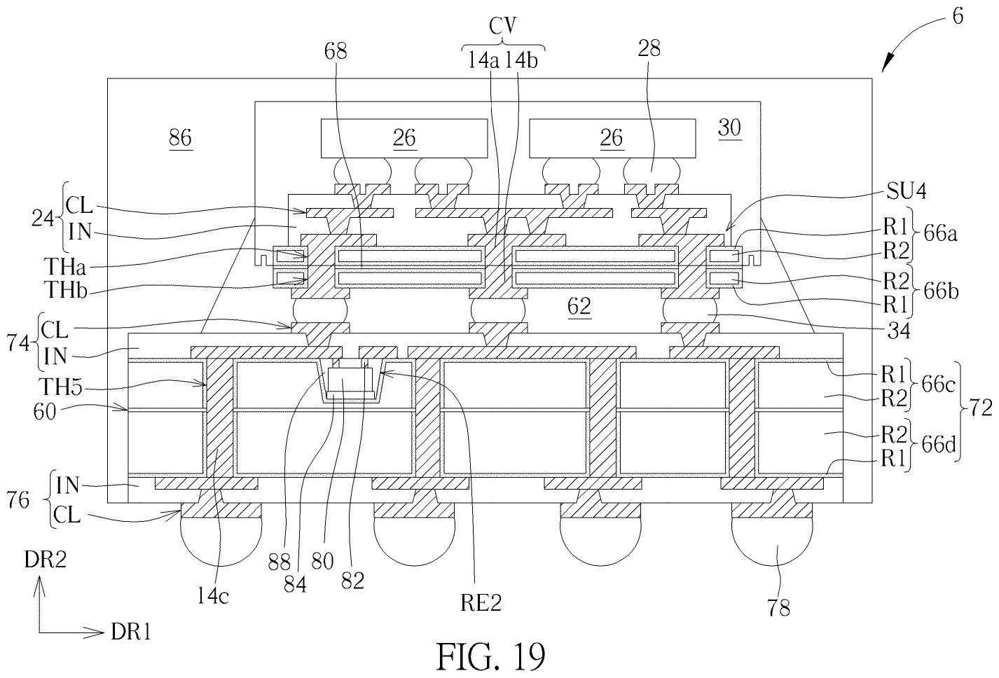

Refer to FIG. 19. FIG. 19 schematically illustrates a cross-sectional view of a package device according to a sixth embodiment of the present disclosure. As shown in FIG. 19, the package device 6 provided by this embodiment may include a substrate structure unit SU4, the circuit structure 24, and the electronic units 26, wherein the circuit structure 24 is disposed on the substrate structure unit SU4, and the electronic units 26 are bonded and electrically connected to the circuit structure 24 through the connection elements 28. A difference between the substrate structure unit SU4 of this embodiment and the substrate structure units of the above-mentioned embodiments is that the substrate structure unit SU4 may include a plurality of substrates stacked. In the embodiment of FIG. 19, the substrate structure unit SU4 takes a substrate 66a and a substrate 66b for example, but not limited thereto. The substrate 66a and the substrate 66b may be bonded to each other through an intermediate layer 68. The intermediate layer 68 may, for example, include an inorganic material or an organic material. The inorganic material may include materials with similar characteristics of glass, such that after the annealing process, the material of the intermediate layer 68 may be identical or similar to the material of the substrate 66a and the material of the substrate 66b. The inorganic material may, for example, include silicon dioxide, tetraethoxysilane (TEOS), materials with silicon, glass-like materials, or other suitable materials. The organic material may include a material heterogeneous with glass, such as glue or other suitable materials.

The substrate 66a may include a plurality of through holes THa, and the substrate 66b may include a plurality of through holes THb. The substrate 66a and the substrate 66b each may include the first portion R1 and the second portion R2. In this embodiment, the first portion R1 of the substrate 66a may be adjacent to a surface of the substrate 66a facing the substrate 66b, a surface of the substrate 66a opposite to the substrate 66b, and a side wall of the through hole THa, and the first portion R1 of the substrate 66b may be adjacent to a surface of the substrate 66b facing the substrate 66a, a surface of the substrate 66b opposite to the substrate 66a, and a side wall of the through hole THb, but not limited thereto. The substrate 66a and the substrate 66b may, for example, be identical to the unit substrate 12a of FIG. 13, but not limited thereto. The substrate structure unit SU4 may include a plurality of conductive elements 14a and a plurality of conductive elements 14b, wherein the conductive elements 14a may be disposed in the through holes THa and may be extended to the surface of the substrate 66a away from the substrate 66b, and the conductive elements 14b may be disposed in the through holes THb and may be extended to the surface of the substrate 66b away from the substrate 66a.

In some embodiments, the substrate 66a and the substrate 66b of the substrate structure unit SU4 each may alternatively be replaced with the unit substrate 12a of FIG. 7. Or, the substrate 66a and the substrate 66b of the substrate structure unit SU4 may alternatively adopt the unit substrate 12a of FIG. 16. Under this condition, the first portion R1 of the substrate 66a may be adjacent to an upper surface of the substrate 66a and not adjacent to the side wall of the through hole THa nor the lower surface of the substrate 66a. Similarly, the first portion R1 of the substrate 66b may be adjacent to the lower surface of the substrate 66b and not adjacent to the side wall of the through hole THb nor the upper surface of the substrate 66b. In some embodiments, the substrate structure unit SU4 may alternatively further include the buffer layer 18 of FIG. 9 disposed on the upper surface of the substrate 66a, the side wall of the through hole THa, the lower surface of the substrate 66b, and the side wall of the through hole THb.

In this embodiment, each conductive element 14a and the corresponding conductive element 14b may form a conductive via CV penetrating the substrate 66a and the substrate 66b. Since the conductive elements 14a and the conductive elements 14b may be similar or identical to the conductive element 14 of the aforementioned embodiments, which may be referred to the aforementioned contents, and they will not be detailed redundantly herein. In some embodiments, the conductive elements 14a may not be extended to the surface of the substrate 66a opposite to the substrate 66b, and/or the conductive elements 14b may not be extended to the surface of the substrate 66b opposite to the substrate 66a.

As shown in FIG. 19, the circuit structure 24 and the electronic units 26 may adopt the circuit structure and the electronic units 26 of any one of the aforementioned embodiments, which may be referred to the aforementioned contents, and they will not be detailed redundantly herein. In this embodiment, the package device 6 may further include the protection layer 30 disposed on the circuit structure 24 and at least surrounding the electronic units 26. The protection layer 30 may be extended to the side surface of the substrate 66a, but not limited thereto. In some embodiments, the protection layer 30 may alternatively be extended to the side surface of the substrate 66b or may not be extended to the side surface of the substrate 66a.

In this embodiment, the package device 6 may further selectively include the circuit carrier 60, and the substrate structure unit SU4 may be bonded to the circuit carrier 60 through the connection elements 34, but not limited thereto. In some embodiments, the package device 6 may further include the adhesive layer 62 disposed between the circuit carrier 60 and the substrate structure unit SU4, but not limited thereto. The adhesive layer 62 may, for example, be identical to the adhesive layer 62 of FIG. 18, which may be referred to the aforementioned contents, and it will not be detailed redundantly herein.

In the embodiment of FIG. 19, the circuit carrier 60 may selectively include a core substrate 72 and a plurality of conductive elements 14c, wherein the core substrate 72 may have a plurality of through holes TH5, and the conductive elements 14c may respectively be disposed in the corresponding through holes TH5 and may penetrate the core substrate 72. In other words, the conductive elements 14c may be conductive vias. In this embodiment, the conductive elements 14c may not be extended to a surface of a substrate 66c away from a substrate 66d and a surface of the substrate 66d away from the substrate 66c, but not limited thereto. In some embodiments, the conductive elements 14c may be extended to the surface of the substrate 66c away from the substrate 66d and/or the surface of the substrate 66d away from the substrate 66c. Other parts of the conductive elements 14c may, for example, be identical or similar to the conductive elements 14 in the above-mentioned contents, and hence, they will not be detailed redundantly herein. The core substrate 72 may include a plurality of substrates, such as including the substrate 66c and the substrate 66d. The substrate 66c and the substrate 66d may each include the first portion R1 and the second portion R2, wherein positions of the first portion R1 and the second portion R2 may, for example, respectively similar or identical to the positions of the first portion R1 and the second portion R2 of the substrate 66a and the substrate 66b, and they will not be further elaborated herein. The substrate 66c and the substrate 66d may be bonded to each other and each of them may have a plurality of through holes, wherein one of the through holes of the substrate 66c and the corresponding through hole of the substrate 66d may form a through hole TH5. A thickness of the substrate 66d may be greater than a thickness of the substrate 66c, such that the substrate 66d may support elements disposed thereon. In some embodiments, a thickness of the core substrate 72 may be greater than a sum of a thickness of the substrate 66a and a thickness of the substrate 66b. Materials of the substrate 66a, the substrate 66b, the substrate 66c, and the substrate 66d of this embodiment may be similar or identical to the substrate 12 of FIG. 2, which may be referred to the aforementioned contents, and they will not be detailed redundantly herein.

As shown in FIG. 19, the circuit carrier 60 may further selectively include a circuit structure 74 and a circuit structure 76 respectively disposed on an upper side and a lower side of the core substrate 72. The circuit structure 74 may be electrically connected to one end of each conductive element 14c and may be used to electrically connect the conductive vias CV to the corresponding conductive elements 14c, and the circuit structure 76 may electrically connect the other end of each conductive element 14c to a corresponding connection element 78 to further be electrically connected to other elements. Other elements may include a circuit board or other electronic elements, but not limited thereto. The circuit structure 74 and/or the circuit structure 76 may be similar or identical to the circuit structure 24 of FIG. 13, which may be referred to the aforementioned contents, and they will not be detailed redundantly herein. According to some embodiments, the circuit carrier 60 may alternatively not include the circuit structure 74 and/or the circuit structure 76. In some embodiments, the core substrate 72 of FIG. 19 may alternatively include bismaleimide triazine (BT) resin or other suitable core substrate materials.

In the embodiment of FIG. 19, the substrate 66c of the core substrate 72 may further have a trench RE2, and the package device 6 may further include an electronic element 80 disposed in the trench RE2. An active surface of the electronic element 80 may face the circuit structure 74 and may be electrically connected to the circuit structure 74 through connection elements 82. Disposing the electronic element 80 in the trench RE2 may give aid to shortening the signal transmission path between the electronic element 80 and the electronic units 26. The electronic element 80 may, for example, be attached in the trench RE2 through an adhesive layer 84, but not limited thereto. The electronic element 80 may, for example, include a passive element or other suitable element. According to some embodiments, the electronic element 80 may be selectively overlapped with at least one of the electronic units 26. According to some embodiments, the electronic element 80 may not be overlapped with the electronic units 26. In some embodiments, the circuit carrier 60 may alternatively be identical to the circuit carrier 60 of FIG. 18, but not limited thereto.

In some embodiments, the package device 6 may further include a protection layer 86 disposed on the protection layer 30, the adhesive layer 62, and the circuit carrier 60 to protect the electronic units 26, the substrate structure unit SU4, and the circuit carrier 60. The protection layer 86 may, for example, include a package material, but not limited thereto.

As shown in FIG. 19, in the manufacturing method of the package device 6, the substrate 66a and the substrate 66b may be separately formed according to the embodiment of FIG. 10 and FIG. 11. That is, after the second modification process, the conductive elements 14a and the conductive elements 14b are respectively formed in the through holes THa of the substrate 66a and the through holes THb of the substrate 66b. Then, the circuit structure 24 is formed on the substrate 66a, and the electronic units 26 are bonded to the circuit structure 24. Afterwards, the substrate 66a is bonded to the substrate 66b to form the substrate structure unit SU4, but not limited thereto. In this embodiment, the protection layer 30 may, for example, be formed before step of bonding the substrate 66a to the substrate 66b, but not limited thereto. In some embodiments, the method of forming the substrate structure unit SU4 may alternatively adopt the embodiment of FIG. 2 to FIG. 7, the embodiment of FIG. 8 and FIG. 9, or the embodiment of FIG. 14 to FIG. 16.

In this embodiment, the method of forming the core substrate 72 and the conductive elements 14c may, for example, adopt the embodiment of FIG. 2 to FIG. 7, and the second modification process is performed after the substrate 66c and the substrate 66d are bonded to simultaneously form the first portions R1 and the second portions R2 of the substrate 66c and the substrate 66d, but not limited thereto. Since the trench RE2 may be formed before the second modification process, the first portion R1 of the substrate 66c may also be adjacent to a side wall and a bottom surface of the trench RE2. In some embodiments, the method of forming the circuit carrier 60 may alternatively adopt the embodiment of FIG. 8 and FIG. 9, the embodiment of FIG. 10 to FIG. 13, or the embodiment of FIG. 14 to FIG. 16.

In the manufacturing method of the package device 6 of FIG. 19, after forming the core substrate 72 and the conductive elements 14c, the electronic element 80 may be disposed in the trench RE2, and then, an insulation layer 88 may be formed in the trench RE2. Afterwards, the circuit structure 74 is formed on the surface of the substrate 66c opposite to the substrate 66d and on the insulation layer 88. Besides, before or after the circuit structure 74 is formed, the circuit structure 76 may be formed on the surface of the substrate 66d opposite to the substrate 66c, and then, the connection elements 78 are formed on the circuit structure 76, such that the circuit carrier 60 may be formed. After completing the circuit carrier 60, the substrate structure unit SU4 formed with the protection layer 30 may be bonded to the circuit carrier 60 through the connection elements 34. Then, the protection layer 86 is formed on the protection layer 30 and the circuit carrier 60. In this embodiment, the protection layer 86 may be extended to the side surfaces of the substrate 66c and the substrate 66d, but not limited thereto. The manufacturing method of the package device 6 of the present disclosure may not be limited to the aforementioned contents and may be adjusted based on requirements.

Refer to FIG. 20. FIG. 20 schematically illustrates a cross-sectional view of a package device according to a seventh embodiment of the present disclosure. As shown in FIG. 20, the package device 7 provided by this embodiment may include a substrate structure unit SU5, a circuit structure 241, a circuit structure 242, and at least one electronic unit 26, wherein the circuit structure 241 and the circuit structure 242 are respectively disposed on two opposite sides of the substrate structure unit SU5, and the electronic unit 26 may be bonded and electrically connected to the circuit structure 241 through the connection elements 28. The substrate structure unit SU5 of this embodiment may include the unit substrate 12a and a plurality of conductive elements 14d, and the conductive elements 14d are respectively disposed in the through holes TH1 of the unit substrate 12a. The unit substrate 12a may include the first portion R1 and the second portion R2 similar to the first portion R1 and the second portion R2 of any one of the aforementioned embodiments, and they will not be elaborated redundantly herein. The conductive elements 14d may, for example, not be extended to the upper surface 12S1 and the lower surface 12S2 of the unit substrate 12a, but not limited thereto. In some embodiments, the conductive elements 14d may be extended to the upper surface 12S1 and/or the lower surface 12S2 of the unit substrate 12a. Other parts of the conductive element 14d may be similar or identical to the conductive element 14 from the above-mentioned contents, and they are not elaborated redundantly herein.

The through holes TH1 of the unit substrate 12a of this embodiment may, for example, be an hourglass shape in the cross-sectional view. Under this condition, a portion of the through hole TH1 having the minimum width W1 may be at the center of the through hole TH1, for example the position furthest away from the upper surface 12S1 and the lower surface 12S2. A portion of the through hole TH1 having the maximum width W2 may be at a position closest to the upper surface 12S1 and/or the lower surface 12S2. The cross-sectional shape of the through hole TH1 of the present disclosure is not limited thereto.

In the embodiment of FIG. 20, the substrate structure unit SU5 may selectively adopt the embodiment of FIG. 9 and may further include the buffer layer 18 disposed on the upper surface 12S1, the lower surface 12S2, and the side wall 123 of the through hole TH1 of the unit substrate 12a, and a portion of the buffer layer 18 may be disposed between the conductive elements 14d and the unit substrate 12a. The buffer layer 18 of this embodiment may be identical to the buffer layer 18 of FIG. 9, which may be referred to the above-mentioned contents, and it is not elaborated redundantly herein. The substrate structure unit SU5 of the present disclosure may not be limited to the structure shown in FIG. 20 and may be replaced with the package device 1 of FIG. 7, the package device 2 of FIG. 9, the substrate structure unit SU1 of FIG. 13, the package device 4 of FIG. 16, the substrate structure unit SU2 of FIG. 17, the core substrate 52 of FIG. 18, the substrate structure unit SU4 of FIG. 19, or the circuit carrier 60 of FIG. 19.

In some embodiments, as shown in FIG. 20, the unit substrate 12a may further selectively have a trench RE3, and the first portion R1 may be closer to a side wall 1285 and a bottom surface 1286 of the trench RE3 than the second portion R2. In addition, the package device 7 may further include an electronic element 126 disposed in the trench RE3. An active surface of the electronic element 126 may face the circuit structure 241 and may be electrically connected to the circuit structure 241 through bonding pads 128. Disposing the electronic element 126 in the trench RE3 may give aid to shortening the signal transmission path between the electronic element 126 and the electronic units 26. The electronic element 126 may, for example, be attached to the trench RE3 through an adhesive layer 130, but not limited thereto. The electronic element 126 may, for example, include a resistor, a capacitor, an inductor, a combination of the aforementioned elements, or other suitable elements.

The circuit structure 241 and the circuit structure 242 may be similar to the circuit structure 24 of the aforementioned embodiments and may include at least one conductive layer CL and at least one insulation layer IN, and they may be referred to the above-mentioned contents. In this embodiment, the circuit structure 241 and the circuit structure 242 may each include the plurality of conductive layers CL and the plurality of insulation layer IN, but not limited thereto.

As shown in FIG. 20, the package device 7 may further include a protection layer 132 disposed on the circuit structure 241 and the upper surface 12S1 of the unit substrate 12a to protect the circuit structure 241. The protection layer 132 may have openings exposing bonding pads of the circuit structure 241, such that the bonding pads 26p of the electronic unit 26 may be bonded to the bonding pads of the circuit structure 241 through the corresponding bonding pads 28. In some embodiments, the package device 7 may further include another protection layer 134 disposed on the circuit structure 242 and the lower surface 12S2 of the unit substrate 12a to protect the circuit structure 242. The protection layer 134 may also have openings exposing bonding pads of the circuit structure 242, such that bonding pads 110 may respectively be bonded to the corresponding bonding pads of the circuit structure 242. The protection layer 132 and the protection layer 134 may include a solder resist material or other suitable materials.

In some embodiments, the package device 7 may include the plurality of electronic units 26, wherein the electronic units 26 may include the electronic unit 26a and the electronic unit 26b. The electronic unit 26a may, for example, be a control chip, and the electronic unit 26b may, for example, be a photonic integrated circuit. The electronic unit 26b may, for example, include a photoelectric conversion element, a light wave guide, a signal processing element, a micro-electromechanical element, and/or an assembled structure of other suitable elements. Under this circumstance, the package device 7 may further selectively include an optical fiber 136 assembled on the electronic unit 26b, such that the electronic unit 26b may receive a light signal through the optical fiber 136.

In some embodiments, the package device 7 may further selectively include another adhesive layer 120 disposed between the electronic units 26 and the circuit structure 241. The adhesive layer 120 may be similar or identical to the adhesive layer 62 of FIG. 18 or FIG. 19, which may be referred to the aforementioned contents, and it is not elaborated redundantly herein. The package device may further optionally include a protection layer 122 at least surrounding the electronic units 26. In some embodiments, the protection layer 122 may selectively surround the circuit structure 241 or may surround the circuit structure 241 and the unit substrate 12a. The protection layer 122 may include a package material, such as including EMC or other suitable materials. In the present disclosure, an element “surrounds” another element may refer to in the cross-sectional view of the package device, the element at least contacts a side surface of the another element.

According to some embodiments, the method of forming the package device 7 may include after the metallization process of forming the conductive elements 14d, forming a plurality of circuit structures 241 and a plurality of protection layers 132 on a side of the patterned substrate, disposing the plurality of electronic units 26 on the plurality of circuit structures 241, forming the protection layer 122 on the circuit structure 241 and the patterned substrate, and forming a plurality of circuit structures 242 on another side of the patterned substrate to form a plurality of package devices 7. Then, the method of forming the package device 7 may further include a singulation process to divide the package devices 7. That is, the plurality of package devices 7 may be formed at the same time, and the singular, independent, and qualified package device 7 may be formed through the singulation process. The singulation process includes a blade cutting process or a laser cutting process. For example, the package devices 7 separated from each other may be formed using a laser to cut the patterned substrate from a side of the protection layer 122. According to some embodiments, after forming a stack of all the elements or after forming the circuit structure 241 and the circuit structure 242 respectively on two sides of the patterned substrate with the through holes TH1, the package devices 7 separated from each other may be formed using the laser to cut the patterned substrate simultaneously from the circuit structure 241 and the circuit structure 242 on two sides of the patterned substrate. The sigulation process described above may be applied to all the manufacturing processes of the package device of the present disclosure. According to some embodiments, the wavelength of the laser used for cutting may be different from the wavelength of the laser used in the modification process, for example, the wavelength of the laser used for cutting may be greater than the wavelength of the laser used for the first modification process.

In summary, in the package device and the manufacturing method thereof of the present disclosure, since the second modification process may form the first portion including compressive stress and the second portion including tensile stress in the substrate, and the first portion is closer to the surface of the substrate than the second portion, the possibility of the crack deteriorating or expanding may be reduced, the reliability of the package device may be enhanced, and/or the product yield may be enhanced when the following thermal processes are performed under the condition that there is a crack in the substrate.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A package device, comprising:
a substrate comprising a through hole, a first portion, and a second portion, wherein the through hole penetrates the first portion and the second portion, and a first thickness of the first portion is less than a second thickness of the second portion; and
a conductive element disposed in the through hole,
wherein the first portion of the substrate comprises compressive stress, and the second portion of the substrate comprises tensile stress.

2. The package device according to claim 1, wherein a concentration of potassium of the first portion is greater than a concentration of potassium of the second portion.

3. The package device according to claim 1, wherein the first thickness of the first portion is less than or equal to 5 micrometers.

4. The package device according to claim 1, further comprising a buffer layer disposed on the substrate, wherein a dissipation factor of the buffer layer is less than a dissipation factor of the first portion.

5. The package device according to claim 1, further comprising a circuit structure and a connection element, wherein the substrate is disposed between the circuit structure and the connection element, and the circuit structure is electrically connected to the connection element through the conductive element.

6. The package device according to claim 5, further comprising an electronic unit and a protection layer, wherein the electronic unit is disposed on the circuit structure, and the protection layer surrounds the electronic unit.

7. The package device according to claim 6, wherein the protection layer contacts the substrate.

8. The package device according to claim 1, wherein the substrate comprises glass.

9. The package device according to claim 1, wherein the second portion comprises an alkali metal, and a weight percentage of the alkali metal in the second portion is less than 10 wt %.

10. The package device according to claim 1, wherein the first portion is disposed between the second portion and the conductive element.

11. A manufacturing method of a package device, comprising:
providing a substrate;
performing a first modification process on the substrate;
performing an etching process to form a patterned substrate, wherein the patterned substrate comprises a through hole;
performing a first inspection process on the patterned substrate to determine if the patterned substrate is a qualified product after the etching process;
when the patterned substrate is determined to be the qualified product, performing a second modification process to form a first portion and a second portion in the patterned substrate, wherein the patterned substrate comprises a surface, the first portion is closer to the surface than the second portion, and a first thickness of the first portion is less than a second thickness of the second portion, wherein the first portion comprises compressive stress, and the second portion comprises tensile stress; and
performing a metallization process to form a conductive element in the through hole.

12. The manufacturing method of the package device according to claim 11, wherein the second modification process comprises disposing the patterned substrate into a solution, wherein the solution comprises a first alkali metal.

13. The manufacturing method of the package device according to claim 12, wherein the substrate comprises a second alkali metal, and an atomic mass of the first alkali metal is greater than an atomic mass of the second alkali metal.

14. The manufacturing method of the package device according to claim 12, wherein a concentration of the first alkali metal of the first portion is greater than a concentration of the first alkali metal of the second portion.

15. The manufacturing method of the package device according to claim 11, further comprising performing a second inspection process between the first modification process and the etching process.

16. The manufacturing method of the package device according to claim 11, further comprising performing a third inspection process between the second modification process and the metallization process.

17. The manufacturing method of the package device according to claim 11, further comprising performing a cutting process after the metallization process.

18. The manufacturing method of the package device according to claim 11, further comprising forming a buffer layer on the surface of the patterned substrate between the second modification process and the metallization process.

19. The manufacturing method of the package device according to claim 11, further comprising performing a cutting process between the first inspection process and the second modification process.

20. The manufacturing method of the package device according to claim 11, wherein the metallization process is performed before the second modification process is performed.
